(19) United States
(12) Patent Application Publication
(10) Pub. No.: US 2013/0152857 A1
(43) Pub. Date: Jun. 20, 2013

(54) Substrate Processing Fluid Delivery System and Method

(71) Applicants: Jason Wright, Saratoga, CA (US); Tony P. Chiang, Campbell, CA (US)

(72) Inventors: Jason Wright, Saratoga, CA (US); Tony P. Chiang, Campbell, CA (US)

(73) Assignee: Intermolecular, Inc., San Jose, CA (US)

(21) Appl. No.: 13/327,597

(22) Filed: Dec. 15, 2011

(51) Int. Cl. C23C 16/455; F15D 1/00

(52) U.S. Cl. 118/715; 137/271; 137/1

(57) ABSTRACT

Embodiments provided herein describe substrate processing fluid delivery systems and methods. The substrate processing fluid delivery systems include a flow regulator. A fluid conduit assembly is coupled to the flow regulator and a processing chamber of a substrate processing apparatus. A plurality of processing fluid containers is coupled to the fluid conduit assembly. A plurality of valves is coupled to the fluid conduit assembly. The plurality of valves are configurable to selectively place each of the plurality of processing fluid containers in fluid communication with only the flow regulator or the processing chamber of the substrate processing apparatus through the fluid conduit assembly.

The present invention relates to systems and methods for delivering substrate processing fluids. More particularly, this invention relates to systems and methods for delivering multiple types of processing fluids to a processing chamber of a substrate processing apparatus.

### BACKGROUND OF THE INVENTION

Combinatorial processing enables rapid evaluation of semiconductor, solar, or energy processing operations. The systems supporting the combinatorial processing are flexible to accommodate the demands for running the different processes either in parallel, serial, or some combination of the two.

Some exemplary processing operations include operations for adding (depositions) and removing layers (etch), defining features, preparing layers (e.g., cleans), doping, etc. Similar processing techniques apply to the manufacture of integrated circuit (IC) semiconductor devices, flat panel displays, optoelectronics devices, data storage devices, magneto electronic devices, magneto optic devices, packaged devices, and the like. As feature sizes continue to shrink, improvements, whether in materials, unit processes, or process sequences, are continually being sought for the deposition processes. However, semiconductor and solar companies conduct research and development (R&D) on full wafer processing through the use of split lots, as the conventional deposition systems are designed to support this processing scheme. This approach has resulted in ever escalating R&D costs and the inability to conduct extensive experimentation in a timely and cost effective manner. Combinatorial processing as applied to semiconductor, solar, or energy manufacturing operations enables multiple experiments to be performed at one time in a high throughput manner. Equipment for performing the combinatorial processing and characterization must support the efficiency offered through the combinatorial processing operations.

### BRIEF DESCRIPTION OF THE DRAWINGS

Various embodiments of the invention are disclosed in the following detailed description and the accompanying drawings:

FIG. 1 is a schematic block diagram of a substrate processing fluid delivery system according to one embodiment of the present invention;

FIG. 2 is a schematic block diagram of a substrate processing fluid delivery system according to another embodiment of the present invention;

FIG. 3 is a schematic block diagram of a substrate processing fluid delivery system according to a further embodiment of the present invention;

FIG. 4 is a schematic block diagram of a substrate processing fluid delivery system according to yet a further embodiment of the present invention;

FIG. 5 is a schematic block diagram of a substrate processing fluid delivery system according to yet a further embodiment of the present invention;

FIG. 6 is a cross-sectional view of a substrate processing apparatus according to one embodiment of the present invention;

FIG. 7 is a schematic diagram of a combinatorial processing and evaluation technique; and

FIG. 8 is a simplified schematic diagram illustrating a general methodology for combinatorial process sequence integration.

### DETAILED DESCRIPTION

A detailed description of one or more embodiments is provided below along with accompanying figures. The detailed description is provided in connection with such embodiments, but is not limited to any particular example. The scope is limited only by the claims and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

Embodiments described herein provide substrate processing fluid delivery systems and methods. In some embodiments, the substrate processing fluid delivery system includes a flow regulator (e.g., a mass flow controller (MFC)) coupled to a fluid conduit assembly that is in turn coupled to a processing chamber of a substrate processing apparatus (e.g., a chemical vapor deposition (CVD) tool). Typically, the fluid conduit is coupled to the processing chamber through an interface. Typical interfaces include fittings, connectors, flanges, etc. Multiple processing fluid containers (e.g., ampoules) are coupled to the fluid conduit assembly, as is a series of valves. The valves and the fluid conduit assembly are arranged so that the valves may be configured to selectively place each of the ampoules in fluid communication with only the flow regulator (and/or any fluid supply coupled to the flow regulator) or the processing chamber of the substrate processing apparatus through the fluid conduit assembly.

As such, the system allows for any one of the processing fluids (i.e., the fluid within one of the ampoules) to be delivered to the processing chamber at a time. Likewise, the system allows for any one of the processing fluids to be placed in fluid communication with the flow regulator at a time. The system may be particularly beneficial for “combinatorial” processing in which different fluids are selectively exposed to different portions of a substrate in the processing chamber. According to one aspect of the present invention, this is accomplished using a simple, inexpensive array of components, which minimizes manufacturing costs.

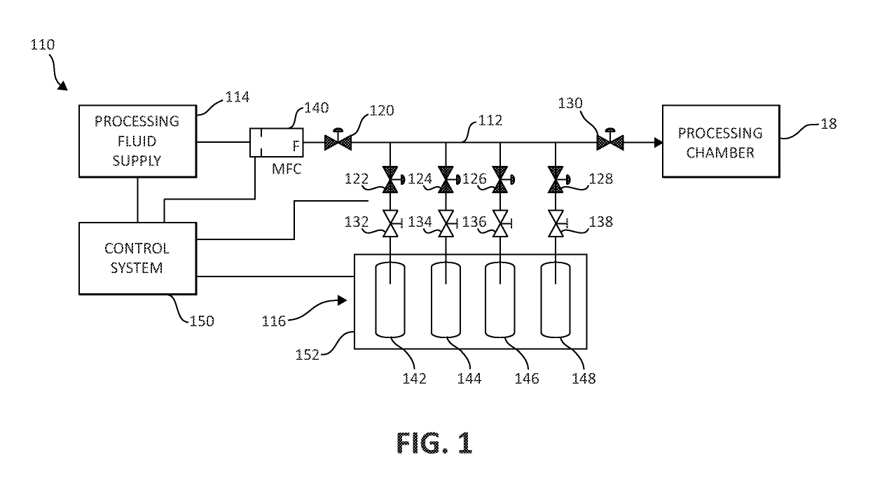

FIG. 1 illustrates a substrate processing fluid delivery system 110 according to one embodiment of the present invention. The system 110 includes a fluid conduit assembly 112 that interconnects a processing fluid supply 114, an array of ampoules 116, and a processing chamber 118 of a substrate processing tool. More specifically, the fluid conduit assembly 112 provides for fluid communication between the processing fluid supply 114, the array of ampoules 116, and the processing chamber 118. However, it should be understood that for purposes of this description the phrase “in fluid communication” may, in some instances, only refer to a state of possible fluid flow between components when the appropriate valves are “opened,” as described below.

As indicated in FIG. 1, the ampoule array 116 includes multiple processing fluid containers (e.g., ampoules) 142-148 that may be considered to be in “parallel” fluid communication with both the processing fluid supply 114 and the processing chamber 118 through the fluid conduit assembly 112. In other embodiments, other types of containers may be used, such as canisters.

Still referring to FIG. 1, the system 110 also includes multiple automated valves 120-130 and multiple manual valves 132-138 coupled in line with the fluid conduit assembly 112. In one embodiment, the automated valves 120-130 are pneumatic valves. Additionally, the system includes a flow regulator (e.g., a MFC) 140 coupled in line with the fluid conduit assembly 112 between the processing fluid supply 114 and automated valve 120.

As indicated by proximity in FIG. 1, automated valve (or flow regulator valve) 120 may be associated with the flow regulator 140, automated valves (or ampoule valves) 122-128 may each be associated with a respective one of the ampoules 142-148, and automated valve (or processing chamber valve) 130 may be associated with the processing chamber 118. Similarly, each of the manual valves 132-138 may be associated with one of the individual ampoules 142-148.

Still referring to FIG. 1, the system 110 further includes a control system 150 and a temperature control unit 152. The control system 150 is in operable communication with the processing fluid supply 114, the flow regulator 140, the automated valves 120-130, and the temperature control unit 152.

The control system (or controller) 150 may include a processor and memory, such as random access memory (RAM) and a hard disk drive, and may be configured to control the operation of the system 110 as described below. Although not shown in detail, the temperature control unit 152 may include heating and/or cooling elements arranged to regulate the temperature of the array of ampoules 116.

In operation, the control system 150 may actuate (i.e., open and/or close) the automated valves 120-130 in order to selectively place each of the individual ampoules 142-148 in fluid communication with only the flow regulator 140 (and the processing fluid supply 114) or the processing chamber 118 through the fluid conduit assembly 112.

For example, if automated valves 120 and 122 are opened, while automated valves 124-130 are closed, ampoule 142 is in fluid communication with, and only with, the flow regulator 140 through the fluid conduit assembly 112. That is, in such a configuration, ampoule 142 is not in fluid communication with the other ampoules 144, 146, and 148 or the processing chamber 118. If automated valve 120 is then closed, and automated valve 130 is opened, ampoule 142 is then only in fluid communication with the processing chamber 118 through the fluid conduit assembly 112.

Similar configurations of the automated valves 120-130 may be used to place each of the remaining ampoules 144, 146, and 148 in fluid communication with only the flow regulator 140 or the processing chamber 118. It should be understood that during operation, the manual valves 132-138 may remain opened. However, a user may manually actuate any of the manual valves 132-138 to isolate the respective ampoules.

In this manner, processing fluids (e.g., inert gases, such as argon) may be injected into any of the ampoules 142-148 from the processing fluid supply 114 through the flow regulator 140. After mixing with the processing fluids within the ampoules 142-148, the processing fluids (e.g., a combination of inert gases and processing liquids) within the ampoules 142-148 may then be delivered into the processing chamber 118. This process may then be repeated for the remaining ampoules 144, 146, and 148.

One method of such delivery may be referred to as a “trapped charge” method, in which a processing gas is injected into one of the ampoules 142-148 from the processing fluid supply 114, and the resulting mixture in the respective ampoule is then delivered into the processing chamber 118 using pressure that has accumulated in the fluid conduit assembly 112 and the respective ampoule.

Specifically, using such a method, a first of the ampoules 142-148 is first placed in fluid communication with only the processing fluid supply 114. The first of the ampoules 142-148 is then placed in fluid communication with only the processing chamber 118. The process may then be repeated for a second of the ampoules 142-148. That is, the second of the ampoules 142-148 may first be placed in fluid communication with only the processing fluid supply 114, before being placed in fluid communication with only the processing chamber 118.

Additionally, a “vapor draw” method may be used in which one of the ampoules 142-148 is placed in fluid communication with the flow regulator 140 and the processing chamber 118 simultaneously. For example, as an inert gas is delivered from the processing fluid supply 114 to the processing chamber 118, vapor from a processing liquid within one of the ampoules 142-148 is drawn into the processing chamber 118.

As such, the system 110 depicted in FIG. 1, as well as those described below, allows for a variety of types of processing fluids to be delivered to the processing chamber 118 with a minimum amount of hardware. For example, although four ampoules 142-148 are included in the example shown in FIG. 1, only one flow regulator 140 and one processing fluid supply 114 are used.

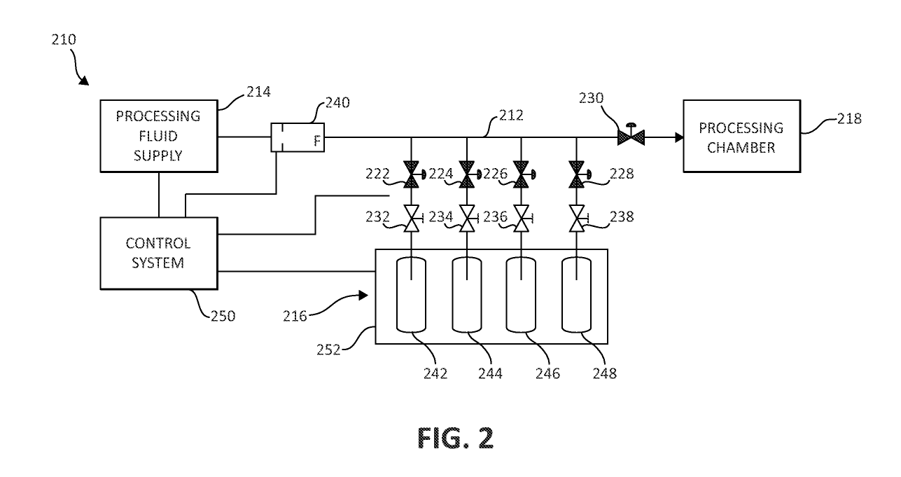

FIG. 2 illustrates a substrate processing fluid deliver system 210 according to another embodiment of the present invention. As with the system 110 shown in FIG. 1, the system 210 of FIG. 2 includes a fluid conduit array 212 that interconnects a processing fluid supply 214, an array of ampoules 216, and a processing chamber 218 of a substrate processing tool. Of particular interest in FIG. 2 is that the automated valves 222-230 do not include a valve specifically associated with the flow regulator 240, thus reducing the total number of valves. However, operation of the system 210 may be similar to that as described with respect to FIG. 1, as the automated valves 222-230 may still be configured to place each of the individual ampoules 242-248 in fluid communication with only the flow regulator 240 or the processing chamber 218.

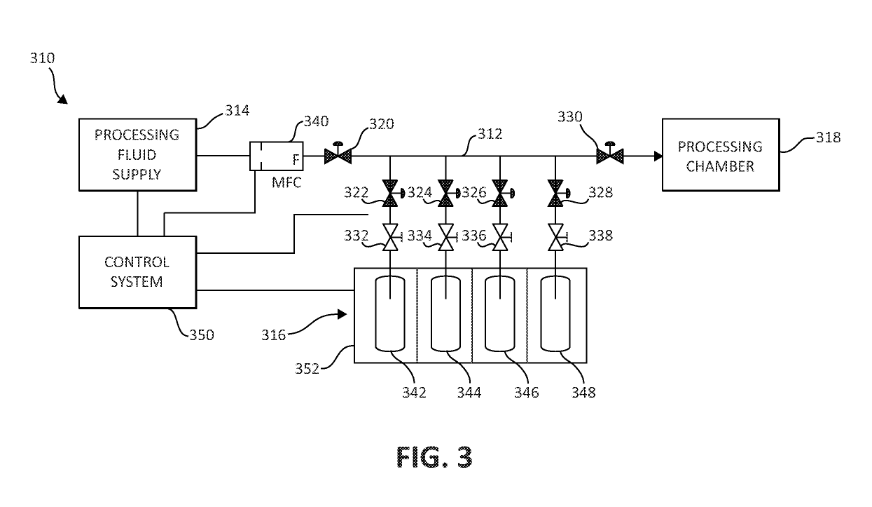

FIG. 3 illustrates a substrate processing fluid deliver system 310 according to a further embodiment of the present invention. The system 310 shown in FIG. 3 may include substantially the same components as those shown in FIGS. 1 and 2. However, of particular interest in the system shown in FIG. 3 is that the temperature control unit 352 is configured to individually regulate the temperature of each of the ampoules 342-348.

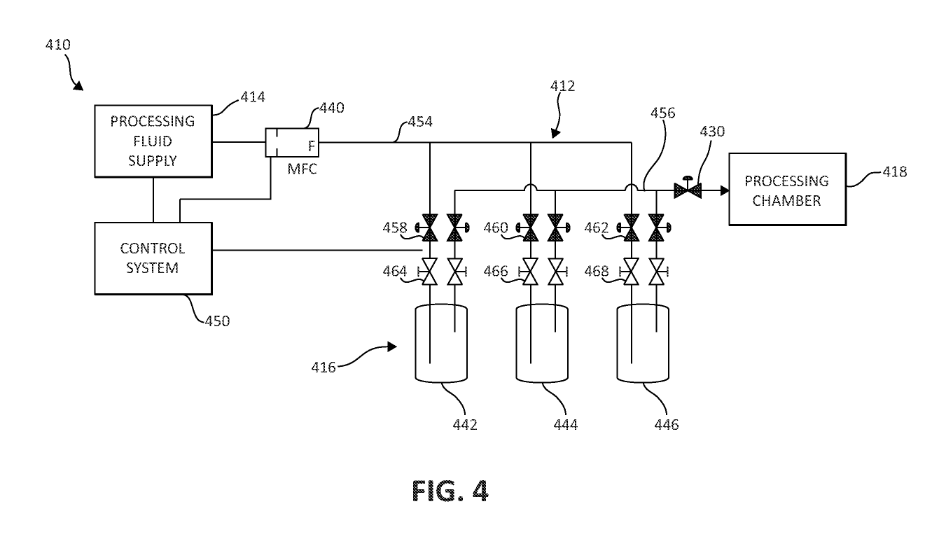

FIG. 4 illustrates a substrate processing fluid deliver system 410 according to a further embodiment of the present invention. Of particular interest in FIG. 4 is that the fluid conduit assembly 412 is separated into a first portion 454 and a second portion 456, each of which is coupled to each of the processing fluid containers 442, 444, and 446 (only three are shown). Additionally, the system 410 includes pairs (or sets) of automated valves 458, 460, and 462 and pairs of manual valves 464, 466, and 468, with each of the pairs being associated with one of the processing fluid containers 442, 444, and 448 and each individual valve within the pairs being in line with either the first portion 454 of the fluid conduit assembly 412 or the second portion 456 of the fluid conduit assembly 412. As such, each valve within the pairs of automated valves 458-462 is in fluid communication with the other valve in the same pair through the respective processing fluid container. As will be appreciate by one skilled in the art, the processing fluid containers 442, 444, and 46 shown in FIG. 4 may be “bubblers.”

The pairs of automated valves 458, 460, and 462, along with automated valve 430, may be configured in a manner similar to the automated valves described above in order selectively place each of the processing fluid containers 442, 444, and 446 in fluid communication with only the flow regulator 440 or the processing chamber 418. The system 410 may then be used in a similar manner to deliver processing fluids to the processing chamber 418.

With respect to the bubblers, as is commonly understood in the art, in CVD processes, for example, the chemicals which are used are often in a liquid state (i.e., liquid sources). In order to be used in CVD processes, liquid sources have to be evaporated or brought into the vapor phase. If the vapor pressure of a particular liquid source is sufficiently high, evaporation may be achieved by heating the liquid source in an evaporator and controlling the vapor flow to the processing chamber of the CVD tool using, for example, a MFC.

However, if the vapor pressure is too low to create a sufficient pressure drop across the MFC, a carrier gas is “bubbled” through the liquid source to enhance evaporation. The devices used for such a process are referred to as bubblers or bubbler assemblies (or systems).

With respect to the embodiment shown in FIG. 4, when one of the pairs of automated valves 458, 460, and 462 are opened, the respective processing fluid container 442, 444, or 446 is placed in fluid communication with the flow regulator 440 and the processing chamber 418. In such a configuration, a carrier gas may be delivered to the respective processing fluid container 442, 44, or 446 to be bubbled through the liquid source held within, and the evaporated liquid may then be delivered to the processing chamber 418. However, as with the other embodiments, the pairs of automated valves 458, 460, and 462 may be configured to selectively place the processing fluid containers 442, 444, and 446 in fluid communication with only the flow regulator 440 or the processing chamber 418.

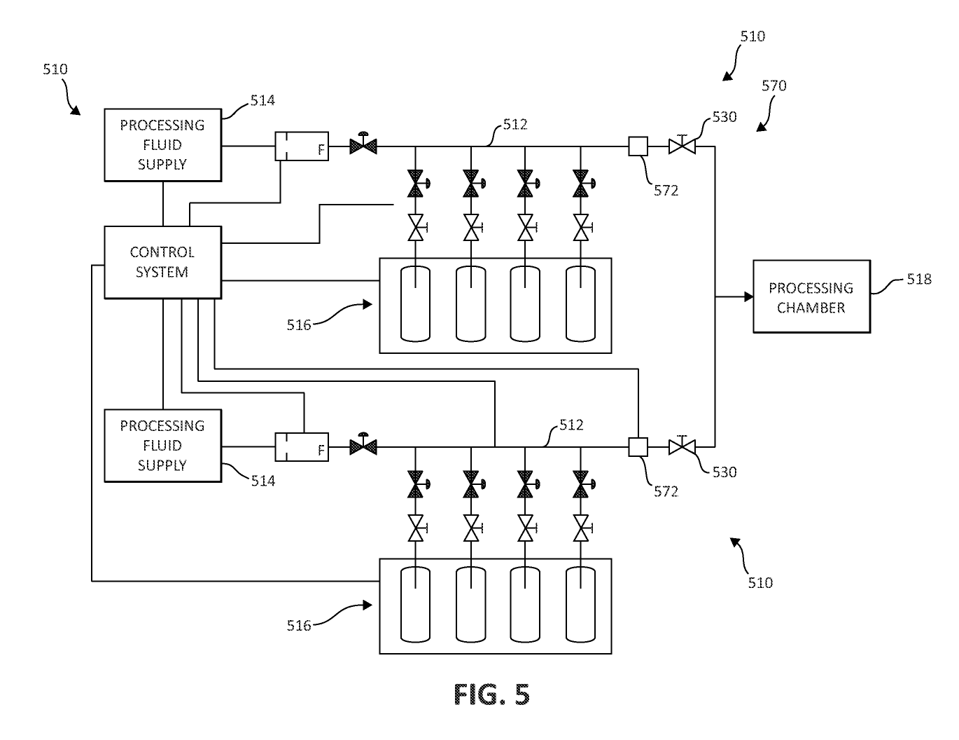

FIG. 5 illustrates a substrate processing fluid deliver system 570 according to a further embodiment of the present invention. The system 570 depicted in FIG. 5 may be a “dual” or “twin” system that essentially includes two of the systems 110 (or sub-systems 510 in FIG. 5) shown in FIG. 1. As such, the system 570 includes, for example, two fluid conduit assemblies 512, two processing fluid supplies 514, and two ampoule arrays 516. However, the fluid conduit assemblies 512 are coupled to a single processing chamber 518. Additionally, each of the sub-systems 510 includes a pressure monitor 572 in line with the respective fluid conduit assembly 512 on a side of automated switch 530 opposite the processing chamber 518.

Each of the sub-systems 510 may be operated in a manner similar to that described above with respect to FIG. 1. The use of multiple sub-systems 510 may allow for a greater variety of processing fluids to be delivered to the processing chamber 518, while minimizing the likelihood of any undesired contamination between the processing fluids.

Although the system 570 in FIG. 5 is depicted as a “dual” system, it should be understood that more than two sub-systems 510 may be utilized. Additionally, although the ampoule arrays 516 are shown as including four ampoules, it should be understood that different numbers of ampoules, and the associated valves, may be used.

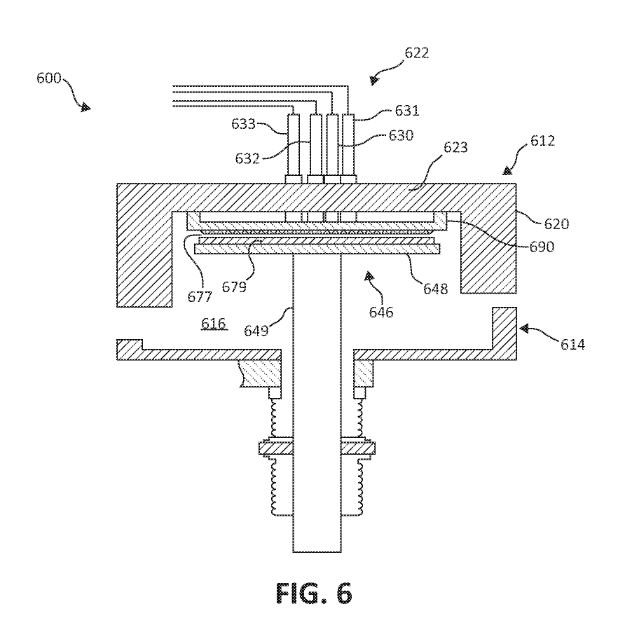

FIG. 6 illustrates a substrate processing apparatus (or tool) 600 in accordance with one embodiment of the present invention. The substrate processing system 600 includes an enclosure assembly 612 formed from a process-compatible material, such as aluminum or anodized aluminum. The enclosure assembly 612 includes a housing 614, which defines a processing chamber 616 (e.g., the processing chamber in FIGS. 1-5), and a vacuum lid assembly 620 covering an opening to the processing chamber 616 at an upper end thereof. Although only shown in cross-section, it should be understood that the processing chamber 616 is enclosed on all sides by the housing 614 and/or the vacuum lid assembly 620.

A process fluid injection assembly 622 is mounted to the vacuum lid assembly 620 and includes a plurality of passageways (or injection ports) 630, 631, 632, and 633 and a showerhead 690 to deliver reactive and carrier fluids into the processing chamber 616 (e.g., from the systems 110, 210, 310, 410, 510 and 70 described above). The showerhead 690 may be formed from any known material suitable for the application, including stainless steel, aluminum, anodized aluminum, nickel, ceramics and the like.

The processing apparatus 600 also includes a heater/lift assembly 646 disposed within processing chamber 616. The heater/lift assembly 646 includes a support pedestal (or substrate support) 648 connected to an upper portion of a support shaft 649. The support pedestal 648 is positioned between the shaft 649 and a lid 623 and may be formed from any process-compatible material, including aluminum nitride and aluminum oxide (Al₂O₃ or alumina).

The support pedestal 648 is configured to hold or support a substrate 679 and may be a vacuum chuck, as is commonly understood, or utilize other conventional techniques, such as an electrostatic chuck (ESC) or physical clamping mechanisms, to prevent the substrate 679 from moving on the support pedestal 648. The support shaft 649 is moveably coupled to the housing 614 so as to vary the distance between support pedestal 648 and the lid 623. The support pedestal 648 may be used to heat the substrate 679 through the use of heating elements (not shown), such as resistive heating elements embedded in the support pedestal 648.

During operation, the substrate processing apparatus 600 establishes conditions in a processing region 677 between an upper surface of the substrate 679 and the showerhead 690 to form the desired material on the surface of the substrate 679, such as a thin film, using, for example, a chemical vapor deposition (CVD) process, such as atomic layer deposition (ALD) or metalorganic chemical vapor deposition (MOCVD).

The manufacture of semiconductor devices, solar devices, optoelectronic devices, etc. (herein collectively called a “device” or “devices”) entails the integration and sequencing of many unit processing steps. As an example, manufacturing typically includes a series of processing steps such as cleaning, surface preparation, deposition, patterning, etching, thermal annealing, and other related unit processing steps. The precise sequencing and integration of the unit processing steps enables the formation of functional devices meeting desired performance metrics such as efficiency, power production, and reliability.

As part of the discovery, optimization and qualification of each unit process, it is desirable to be able to i) test different materials, ii) test different processing conditions within each unit process module, iii) test different sequencing and integration of processing modules within an integrated processing tool, iv) test different sequencing of processing tools in executing different process sequence integration flows, and combinations thereof in the manufacture of devices such as integrated circuits. In particular, there is a need to be able to test i) more than one material, ii) more than one processing condition, iii) more than one sequence of processing conditions, iv) more than one process sequence integration flow, and combinations thereof, collectively known as “combinatorial process sequence integration”, on a single monolithic substrate without the need of consuming the equivalent number of monolithic substrates per material(s), processing condition(s), sequence(s) of processing conditions, sequence(s) of processes, and combinations thereof. This can greatly improve both the speed and reduce the costs associated with the discovery, implementation, optimization, and qualification of material(s), process(es), and process integration sequence(s) required for manufacturing.

Systems and methods for High Productivity Combinatorial (HPC) processing are described in U.S. Pat. No. 7,544,574 filed on Feb. 10, 2006, U.S. Pat. No. 7,824,935 filed on Jul. 2, 2008, U.S. Pat. No. 7,871,928 filed on May 4, 2009, U.S. Pat. No. 7,902,063 filed on Feb. 10, 2006, and U.S. Pat. No. 7,947,531 filed on Aug. 28, 2009, which are all herein incorporated by reference. Systems and methods for HPC processing are further described in U.S. patent application Ser. No. 11/352,077 filed on Feb. 10, 2006, claiming priority from Oct. 15, 2005, U.S. patent application Ser. No. 11/419,174 filed on May 18, 2006, claiming priority from Oct. 15, 2005, U.S. patent application Ser. No. 11/674,132 filed on Feb. 12, 2007, claiming priority from Oct. 15, 2005, and U.S. patent application Ser. No. 11/674,137 filed on Feb. 12, 2007, claiming priority from Oct. 15, 2005 which are all herein incorporated by reference.

HPC processing techniques have been successfully adapted to wet chemical processing such as etching and cleaning. HPC processing techniques have also been successfully adapted to deposition processes such as physical vapor deposition (PVD), atomic layer deposition (ALD), and chemical vapor deposition (CVD).

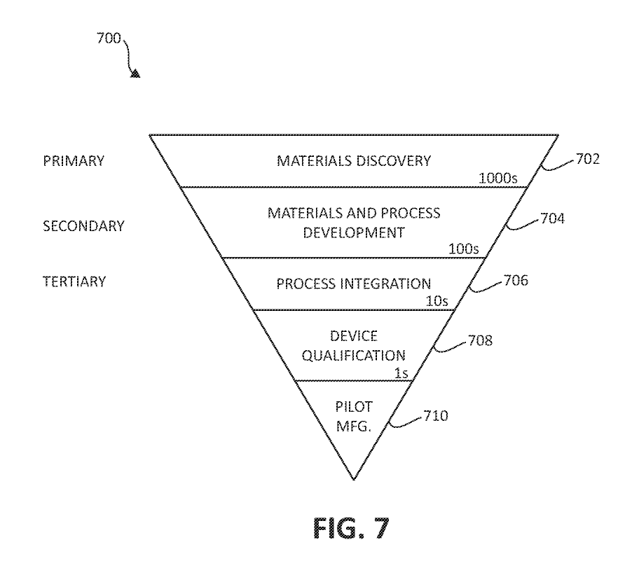

FIG. 7 illustrates a schematic diagram, 700, for implementing combinatorial processing and evaluation using primary, secondary, and tertiary screening. The schematic diagram, 700, illustrates that the relative number of combinatorial processes run with a group of substrates decreases as certain materials and/or processes are selected. Generally, combinatorial processing includes performing a large number of processes during a primary screen, selecting promising candidates from those processes, performing the selected processing during a secondary screen, selecting promising candidates from the secondary screen for a tertiary screen, and so on. In addition, feedback from later stages to earlier stages can be used to refine the success criteria and provide better screening results.

For example, thousands of materials are evaluated during a materials discovery stage, 702. Materials discovery stage, 702, is also known as a primary screening stage performed using primary screening techniques. Primary screening techniques may include dividing substrates into coupons and depositing materials using varied processes. The materials are then evaluated, and promising candidates are advanced to the secondary screen, or materials and process development stage, 704. Evaluation of the materials is performed using metrology tools such as electronic testers and imaging tools (i.e., microscopes).

The materials and process development stage, 704, may evaluate hundreds of materials (i.e., a magnitude smaller than the primary stage) and may focus on the processes used to deposit or develop those materials. Promising materials and processes are again selected, and advanced to the tertiary screen or process integration stage, 706, where tens of materials and/or processes and combinations are evaluated. The tertiary screen or process integration stage, 706, may focus on integrating the selected processes and materials with other processes and materials.

The most promising materials and processes from the tertiary screen are advanced to device qualification, 708. In device qualification, the materials and processes selected are evaluated for high volume manufacturing, which normally is conducted on full substrates within production tools, but need not be conducted in such a manner. The results are evaluated to determine the efficacy of the selected materials and processes. If successful, the use of the screened materials and processes can proceed to pilot manufacturing, 710.

The schematic diagram, 700, is an example of various techniques that may be used to evaluate and select materials and processes for the development of new materials and processes. The descriptions of primary, secondary, etc. screening and the various stages, 702-710, are arbitrary and the stages may overlap, occur out of sequence, be described and be performed in many other ways.

This application benefits from High Productivity Combinatorial (HPC) techniques described in U.S. patent application Ser. No. 11/674,137 filed on Feb. 12, 2007, which is hereby incorporated for reference in its entirety. Portions of the '137 application have been reproduced below to enhance the understanding of the present invention. The embodiments described herein enable the application of combinatorial techniques to process sequence integration in order to arrive at a globally optimal sequence of manufacturing operations by considering interaction effects between the unit manufacturing operations, the process conditions used to effect such unit manufacturing operations, hardware details used during the processing, as well as materials characteristics of components utilized within the unit manufacturing operations. Rather than only considering a series of local optimums, i.e., where the best conditions and materials for each manufacturing unit operation is considered in isolation, the embodiments described below consider interactions effects introduced due to the multitude of processing operations that are performed and the order in which such multitude of processing operations are performed when fabricating a device. A global optimum sequence order is therefore derived and as part of this derivation, the unit processes, unit process parameters and materials used in the unit process operations of the optimum sequence order are also considered.

The embodiments described further analyze a portion or sub-set of the overall process sequence used to manufacture a device. Once the subset of the process sequence is identified for analysis, combinatorial process sequence integration testing is performed to optimize the materials, unit processes, hardware details, and process sequence used to build that portion of the device or structure. During the processing of some embodiments described herein, structures are formed on the processed substrate that are equivalent to the structures formed during actual production of the device. For example, such structures may include, but would not be limited to, contact layers, buffer layers, absorber layers, or any other series of layers or unit processes that create an intermediate structure found on devices. While the combinatorial processing varies certain materials, unit processes, hardware details, or process sequences, the composition or thickness of the layers or structures or the action of the unit process, such as cleaning, surface preparation, deposition, surface treatment, etc. is substantially uniform through each discrete region. Furthermore, while different materials or unit processes may be used for corresponding layers or steps in the formation of a structure in different regions of the substrate during the combinatorial processing, the application of each layer or use of a given unit process is substantially consistent or uniform throughout the different regions in which it is intentionally applied. Thus, the processing is uniform within a region (inter-region uniformity) and between regions (intra-region uniformity), as desired. It should be noted that the process can be varied between regions, for example, where a thickness of a layer is varied or a material may be varied between the regions, etc., as desired by the design of the experiment.

The result is a series of regions on the substrate that contain structures or unit process sequences that have been uniformly applied within that region and, as applicable, across different regions. This process uniformity allows comparison of the properties within and across the different regions such that the variations in test results are due to the varied parameter (e.g., materials, unit processes, unit process parameters, hardware details, or process sequences) and not the lack of process uniformity. In the embodiments described herein, the positions of the discrete regions on the substrate can be defined as needed, but are preferably systematized for ease of tooling and design of experimentation. In addition, the number, variants and location of structures within each region are designed to enable valid statistical analysis of the test results within each region and across regions to be performed.

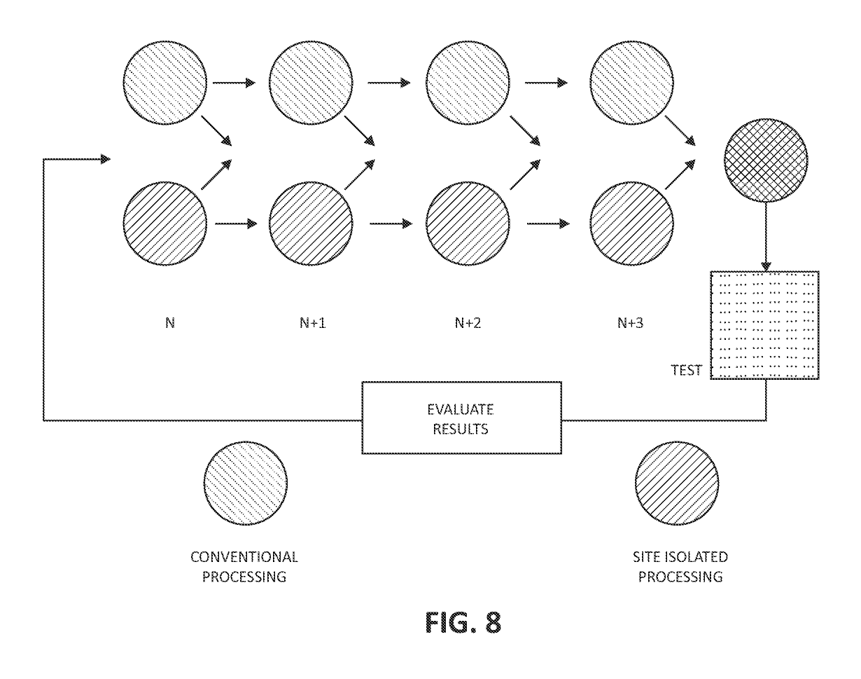

FIG. 8 is a simplified schematic diagram illustrating a general methodology for combinatorial process sequence integration that includes site isolated processing and/or conventional processing in accordance with one embodiment of the invention. In one embodiment, the substrate is initially processed using conventional process N. In one exemplary embodiment, the substrate is then processed using site isolated process N+1. During site isolated processing, an HPC module may be used, such as the HPC module described in U.S. patent application Ser. No. 11/352,077 filed on Feb. 10, 2006. The substrate can then be processed using site isolated process N+2, and thereafter processed using conventional process N+3. Testing is performed and the results are evaluated. The testing can include physical, chemical, acoustic, magnetic, electrical, optical, etc. tests. From this evaluation, a particular process from the various site isolated processes (e.g. from steps N+1 and N+2) may be selected and fixed so that additional combinatorial process sequence integration may be performed using site isolated processing for either process N or N+3. For example, a next process sequence can include processing the substrate using site isolated process N, conventional processing for processes N+1, N+2, and N+3, with testing performed thereafter.

It should be appreciated that various other combinations of conventional and combinatorial processes can be included in the processing sequence with regard to FIG. 2. That is, the combinatorial process sequence integration can be applied to any desired segments and/or portions of an overall process flow. Characterization, including physical, chemical, acoustic, magnetic, electrical, optical, etc. testing, can be performed after each process operation, and/or series of process operations within the process flow as desired. The feedback provided by the testing is used to select certain materials, processes, process conditions, and process sequences and eliminate others. Furthermore, the above flows can be applied to entire monolithic substrates, or portions of monolithic substrates such as coupons.

Under combinatorial processing operations the processing conditions at different regions can be controlled independently. Consequently, process material amounts, reactant species, processing temperatures, processing times, processing pressures, processing flow rates, processing powers, processing reagent compositions, the rates at which the reactions are quenched, deposition order of process materials, process sequence steps, hardware details, etc., can be varied from region to region on the substrate. Thus, for example, when exploring materials, a processing material delivered to a first and second region can be the same or different. If the processing material delivered to the first region is the same as the processing material delivered to the second region, this processing material can be offered to the first and second regions on the substrate at different concentrations. In addition, the material can be deposited under different processing parameters. Parameters which can be varied include, but are not limited to, process material amounts, reactant species, processing temperatures, processing times, processing pressures, processing flow rates, processing powers, processing reagent compositions, the rates at which the reactions are quenched, atmospheres in which the processes are conducted, an order in which materials are deposited, hardware details of the gas distribution assembly, etc. It should be appreciated that these process parameters are exemplary and not meant to be an exhaustive list as other process parameters commonly used in manufacturing may be varied.

Thus, in one embodiment, a substrate processing fluid delivery system is provided. The substrate processing fluid delivery system includes a flow regulator. A fluid conduit assembly is coupled to the flow regulator and a processing chamber of a substrate processing apparatus. A plurality of processing fluid containers is coupled to the fluid conduit assembly. A plurality of valves is coupled to the fluid conduit assembly. The plurality of valves are configurable to selectively place each of the plurality of processing fluid containers in fluid communication with only the flow regulator or the processing chamber of the substrate processing apparatus through the fluid conduit assembly.

In another embodiment, a method is provided for delivering a processing fluid to a processing chamber of a substrate processing apparatus. A fluid conduit assembly is provided. The fluid conduit assembly is coupled to a flow regulator, a plurality of processing fluid containers, a plurality of valves, and the processing chamber of the substrate processing apparatus. The plurality of valves to set to a first configuration. The fluid conduit assembly and the processing fluid containers are arranged such that when the plurality of valves are in the first configuration, one of the plurality of processing fluid containers is in fluid communication with only the flow regulator through the fluid conduit assembly. The plurality of valves are set to a second configuration. The fluid conduit assembly and the processing fluid containers are arranged such that when the plurality of valves are in the second configuration, the one of the plurality of processing fluid containers is in fluid communication with only the processing chamber of the substrate processing apparatus through the fluid conduit assembly.

In a further embodiment, a substrate processing system is provided. The substrate processing system includes a substrate processing apparatus having a processing chamber. A fluid conduit assembly is in fluid communication with the processing chamber of the substrate processing apparatus. A flow regulator is in fluid communication with the fluid conduit assembly. A plurality of processing fluid containers is in fluid communication with the fluid conduit assembly. A plurality of valves is coupled to the fluid conduit assembly. The plurality of valves are configurable to selectively place each of the plurality of processing fluid containers in fluid communication with only the flow regulator or the processing chamber of the substrate processing apparatus through the fluid conduit assembly.

Although the foregoing examples have been described in some detail for purposes of clarity of understanding, the invention is not limited to the details provided. There are many alternative ways of implementing the invention. The disclosed examples are illustrative and not restrictive.

What is claimed:

1. A fluid delivery system comprising:
a flow regulator;
a fluid conduit assembly coupled to the flow regulator
the fluid conduit coupled to an interface between the fluid conduit and a processing chamber;
a plurality of processing fluid containers coupled to the fluid conduit assembly; and
a plurality of valves coupled to the fluid conduit assembly, the plurality of valves being configurable to selectively place each of the plurality of processing fluid containers in fluid communication with either the flow regulator or the interface through the fluid conduit assembly.

2. The fluid delivery system of claim 1, wherein the plurality of valves comprises a flow regulator valve associated with the flow regulator, a processing chamber interface valve associated with the interface of the processing chamber, and a plurality of processing fluid container valves, each of the processing fluid container valves being associated with a respective one of the processing fluid containers.

3. The fluid delivery system of claim 2, wherein the plurality of processing fluid container valves comprises a plurality of sets of processing fluid valves, each of the plurality of sets of processing fluid valves being associated with a respective one of the plurality of processing fluid containers.

4. The fluid delivery system of claim 3, wherein each of the plurality of sets of processing fluid container valves comprises a first processing fluid container valve and a second processing fluid container valve, wherein the first processing fluid container valve and the second processing fluid container valve of each of the plurality of sets of processing fluid container valves are in fluid communication through the respective processing fluid container.

5. The fluid delivery system of claim 1, wherein the flow regulator is a mass flow controller (MFC).

6. The fluid delivery system of claim 1, further comprising a controller in operable communication with the plurality of valves and configured to actuate the valves to selectively place each of the plurality of processing fluid containers in fluid communication with only the flow regulator or the interface of the processing chamber through the fluid conduit assembly.

7. The fluid delivery system of claim 6, wherein the controller is further configured, by actuating the plurality of valves, to:
place a first of the plurality of processing fluid containers in fluid communication with the flow regulator through the fluid conduit assembly, but not in fluid communication with the interface of the processing chamber;
place the first of the plurality of processing fluid containers in fluid communication with the processing chamber through the fluid conduit assembly, but not in fluid communication with the flow regulator;
place a second of the plurality of processing fluid containers in fluid communication with the flow regulator through the fluid conduit assembly, but not in fluid communication with the interface of the processing chamber; and
place the second of the plurality of processing fluid containers in fluid communication with the processing chamber through the fluid conduit assembly, but not in fluid communication with the flow regulator.

8. The fluid delivery system of claim 1, further comprising a processing gas supply in fluid communication with the flow regulator.

9. The fluid delivery system of claim 1, further comprising:
a second flow regulator;
a second fluid conduit assembly coupled to the flow regulator;
the second fluid conduit coupled to an interface between the second fluid conduit and the processing chamber;
a second plurality of processing fluid containers coupled to the second fluid conduit assembly; and
a second plurality of valves coupled to the second fluid conduit assembly, the second plurality of valves being configurable to selectively place each of the second plurality of processing fluid containers in fluid communication with either the second flow regulator or the interface of the processing chamber through the second fluid conduit assembly.

10. The substrate processing fluid delivery system of claim 1, wherein the plurality of processing fluid containers comprises at least one ampoule.

11. A method for delivering a processing fluid to a processing chamber comprising:
providing a fluid conduit assembly coupled to a flow regulator, a plurality of processing fluid containers, a plurality of valves, and an interface of the processing chamber;
setting the plurality of valves to a first configuration, wherein the fluid conduit assembly and the processing fluid containers are arranged such that when the plurality of valves are in the first configuration, one of the plurality of processing fluid containers is in fluid communication with the flow regulator through the fluid conduit assembly, but not in fluid communication with the interface of the processing chamber; and
setting the plurality of valves to a second configuration, wherein the fluid conduit assembly and the processing fluid containers are arranged such that when the plurality of valves are in the second configuration, the one of the plurality of processing fluid containers is in fluid communication with the interface of processing chamber through the fluid conduit assembly, but not in fluid communication with the flow regulator.

12. The method of claim 11, further comprising, when the plurality of valves are in the first configuration, causing a processing gas to be delivered through the flow regulator and the fluid conduit assembly into the one of the plurality of processing fluid containers.

13. The method of claim 12, wherein when the plurality of valves are in the second configuration, a processing fluid is delivered from the one of the plurality of processing fluid containers through the fluid conduit assembly into the processing chamber.

14. The method of claim 13, further comprising:
setting the plurality of valves to a third configuration, wherein the fluid conduit assembly and the processing fluid containers are arranged such that when the plurality of valves are in the third configuration, a second of the plurality of processing fluid containers is in fluid communication with the flow regulator through the fluid conduit assembly, but not in fluid communication with the interface of the processing chamber; and
setting the plurality of valves to a fourth configuration, wherein the fluid conduit assembly and the processing fluid containers are arranged such that when the plurality of valves are in the fourth configuration, the second of the plurality of processing fluid containers is in fluid communication with the processing chamber through the fluid conduit assembly, but not in fluid communication with the flow regulator.

15. The method of claim 11, further comprising:
setting the plurality of valves to a third configuration, wherein the fluid conduit assembly and the processing fluid containers are arranged such that when the plurality of valves are in the third configuration, the one of the plurality of processing fluid containers is in fluid communication with the flow regulator and the interface of the processing chamber through the fluid conduit assembly; and
when the plurality of valves are in the third configuration, causing a processing gas to be delivered through the flow regulator and the fluid conduit assembly into a processing liquid within the one of the plurality of processing fluid containers such that at least some of the processing liquid is evaporated and delivered to the processing chamber through the fluid conduit assembly.

16. A substrate processing system comprising:
a substrate processing apparatus comprising a processing chamber, the process chamber comprising an interface;
a fluid conduit assembly in fluid communication with the interface of the processing chamber;
a flow regulator in fluid communication with the fluid conduit assembly;
a plurality of processing fluid containers in fluid communication with the fluid conduit assembly; and
a plurality of valves coupled to the fluid conduit assembly, the plurality of valves being configurable to selectively place each of the plurality of processing fluid containers in fluid communication with either the flow regulator or the interface of the processing chamber through the fluid conduit assembly.

17. The substrate processing system of claim 16, wherein the substrate processing apparatus is configured to perform one of chemical vapor deposition (CVD), atomic layer deposition (ALD), or metalorganic chemical vapor deposition (MOCVD).

18. The substrate processing system of claim 16, further comprising:
a second fluid conduit assembly in fluid communication with the interface of the processing chamber;
a second flow regulator in fluid communication with the fluid conduit assembly;
a second plurality of processing fluid containers in fluid communication with the second fluid conduit assembly; and
a second plurality of valves coupled to the second fluid conduit assembly, the second plurality of valves being configurable to selectively place each of the second plurality of processing fluid containers in fluid communication with either the second flow regulator or the interface of the processing chamber through the second fluid conduit assembly.

19. The substrate processing system of claim 16, wherein the plurality of processing fluid containers comprises at least one ampoule.

20. The substrate processing system of claim 16, wherein the flow regulator is a mass flow controller (MFC).
